(19) United States
(12) Patent Application Publication
(10) Pub. No.: US 2026/0101813 A1
(43) Pub. Date: Apr. 9, 2026

(54) PLASMA BONDING FORMATION OF DIRECT ELECTRICAL AND FLUIDIC INTERCONNECTS

(71) Applicant: Hewlett-Packard Development Company, L.P., Spring, TX (US)

(72) Inventors: Chien-Hua Chen, Corvallis, OR (US); Michael W. Cumbie, Corvallis, OR (US)

(73) Assignee: Hewlett-Packard Development Company, L.P., Spring, TX (US)

(21) Appl. No.: 19/112,926

(22) PCT Filed: Sep. 6, 2023
(86) PCT No.: PCT/US2023/032106

§ 371 Date: Mar. 18, 2025

Related U.S. Application Data
(60) Provisional application No. 63/409,073, filed on Sep. 22, 2022.

(51) Int. Cl. H10W 80/00; B81C 3/00; H10W 40/40

(52) U.S. Cl. CPC H10W 80/312; B81C 3/001; H10W 40/40; H10W 80/331; B81C 2201/019

(57) ABSTRACT

A device includes first and second substrates. The first substrate has one or multiple first channels and one or multiple first conductors that are exposed at a first surface of the first substrate. The second substrate has one or multiple second channels and one or multiple second conductors that are exposed at a second surface of the first substrate. The first and second substrates are plasma bonded together at the first and second surfaces, forming direct electrical interconnects between the first and second conductors and direct fluidic interconnects between the first and second channels.

### CROSS-REFERENCE TO RELATED PATENT APPLICATIONS

This application claims priority to U.S. Provisional Patent No. 63/409,073, filed on Sep. 22, 2022, the entirety of which is incorporated by reference herein.

### BACKGROUND

Microfluidic devices leverage the physical and chemical properties of liquids and gases at a small scale, such as at a sub-millimeter scale. Microfluidic devices geometrically constrain fluids to precisely control and manipulate the fluids for a wide variety of different applications. Such applications can include digital microfluidic (DMF) and DNA applications, as well as applications as varied as lab-on-a-chip, inkjet, electrophoresis, capacitance sensing, fluidic heat sink, and fluidic sensor probe applications, among other applications. A microfluidic device can include a substrate in which a series of fluidic channels are etched or molded.

### BRIEF DESCRIPTION OF THE DRAWINGS

FIG. 1 is a block diagram of a general example device having direct electrical and fluidic interconnects formed by plasma bonding.

FIGS. 2A, 2B, 2C, 2D, and 2E are diagrams of specific example devices having direct electric and fluidic interconnects formed by plasma bonding.

FIG. 3 is a flowchart of an example method for plasma bonding two substrates together to form a device having direct electrical and fluidic interconnects.

FIG. 4 is a flowchart of an example method for forming a dielectric or amorphous silicon layer on a non-silicon layer of a substrate to permit the substrate to be plasma bonded to another substrate.

FIGS. 5A, 5B, 5C, 5D, and 5E are diagrams illustratively depicting example perform of the method of FIG. 4.

### DETAILED DESCRIPTION

As noted in the background, a microfluidic device can include a substrate in which a series of fluidic channels are formed. The device may also have electrical conductors to communicate with and provide power to integrated circuits (ICs) or other electrical components of the device. These and other components of the device may use the fluidic channels in different ways.

For example, the components may include a processor or other IC that generates heat, in which case the fluidic channels may provide liquid fluid to cool the processor or other IC. The components may include a sensing integrated circuit (IC) that can measure temperature, humidity, pressure, flow rate, light, viscosity, resistance, capacitance and/or other physical or electrical characteristics of a gaseous or liquid fluidic sample, in which case the fluidic channels may provide the fluidic sample to the sensing IC.

The components may include a photonic IC that optically transmits and receives data via light (e.g., photons), in which case the fluidic channels may function as optical paths for the optically transmitted data. The components may include a microfluidics sensor that visually indicates presence or absence of a material of interest, such as a virus, within a fluidic sample, in which case the fluidic channels may provide the fluidic sample and/or a reagent material to the sensor for mixing to provide the visual indication.

Devices that include electrical conductors and ICs or other electrical components can be manufactured by bonding two or more substrates together. Different bonding techniques include adhesive bonding, thermal compression bonding, anodic bonding, glass frit bonding, solder bonding, and solvent bonding. A more recent bonding technique is referred to as plasma bonding, which can also be referred to as plasma-enhanced bonding, plasma-activated bonding, and low-temperature fusion bonding.

Unlike some other bonding techniques, plasma bonding is a direct bonding approach in which direct electrical interconnects are formed without solder between the conductors exposed on one substrate and the conductors exposed on another substrate. Plasma bonding permits significantly greater interconnect density as compared to other bonding techniques. Substrates are usually able to be plasma bonded together because they are silicon substrates. For example, a three-dimensional (3D) device may be fabricated by plasma bonding together multiple silicon substrates, such as wafers, on which different ICs and electrical circuits and components have already been formed.

Techniques described herein extend plasma bonding so that substrates having fluidic channels in addition to electrical conductors are bonded together to form a device. The plasma bonding forms direct fluidic interconnects between the fluidic channels of different substrates as well as direct electrical interconnects between the conductors of different substrates. Such techniques can be employed even with either or both substrates do not have silicon substrates, by first forming a dielectric or amorphous silicon layer on each such substrate so that plasma bonding can be employed.

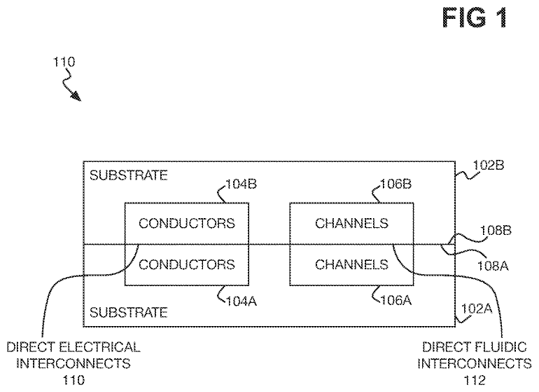

FIG. 1 shows an example device 100. The device includes a first substrate 102A and a second substrate 102B, which may be the same or different type of substrate. For example, either or both substrates 102A and 102B can be a silicon substrate, such as a silicon wafer in the case in which a device layer including an integrated circuit (IC) is formed within or on the substrate. As another example, either or both substrates 102A and 102B can include one or multiple non-silicon layers, such as one or multiple layers of an epoxy or other molding compound in the case of a molded interconnect substrate (MIS). The substrate 102A may form a circuit board to which the substrate 102B is plasma bonded. Furthermore, there may be more than two substrates 102A and 102B plasma bonded together.

The substrates 102A and 102B respectively include one or multiple first conductors 104A and one or multiple second conductors 104B. The conductors 104A and 104B are electrical conductors, and may be copper, tungsten, gold, or another type of conductor. The substrates 102A and 102B respectively include one or multiple first fluidic channels 106A and one or multiple second fluidic channels 106B, which may also be referred to as microfluidic channels. The conductors 104A and the channels 106A are exposed at a first surface 108A of the substrate 102A. Likewise, the conductors 104B and the fluidic channels 106B are exposed at a second surface 108B of the substrate 102B.

The substrates 102A and 102B are plasma bonded together at the surfaces 108A and 108B. Plasma bonding involves using low-frequency plasma to activate a bonding interface at each surface 108A and 108B for low-temperature hydrophilic (fusion) bonding. Covalent bonds are thus formed between the two plasma-activated interfaces at the surfaces 108A and 108B. Upon compressing the substrates 102A and 102B together, direct electrical interconnects 110 between respective of the conductors 104A and 104B are formed, as are direct fluidic interconnects 112 between respective of the fluidic channels 106A and 106B.

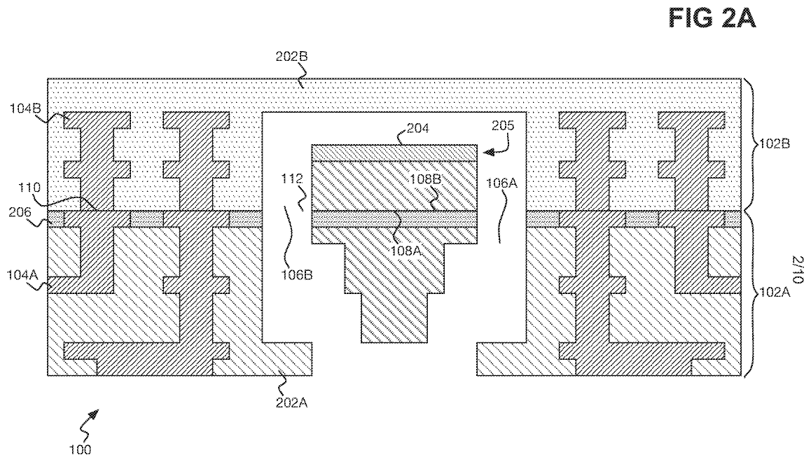

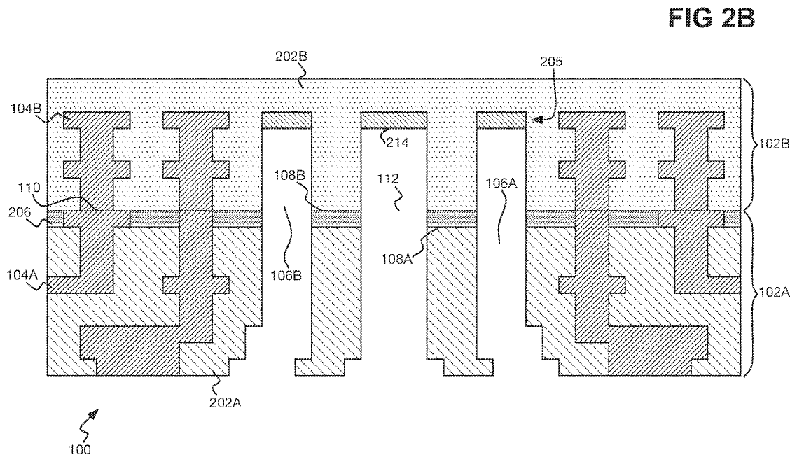

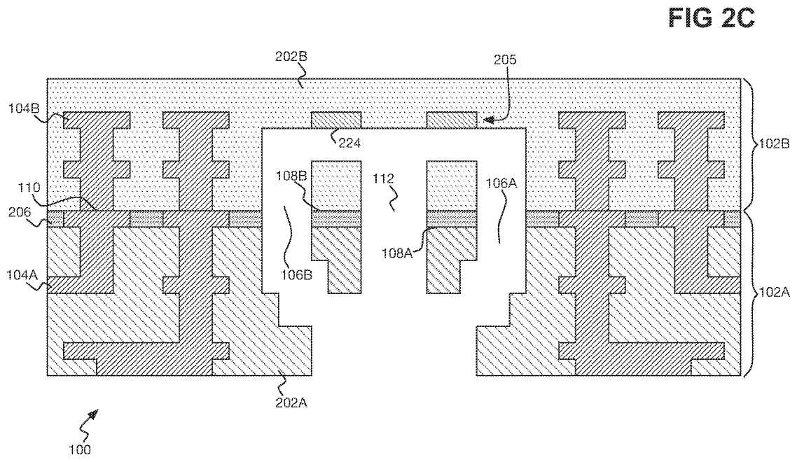

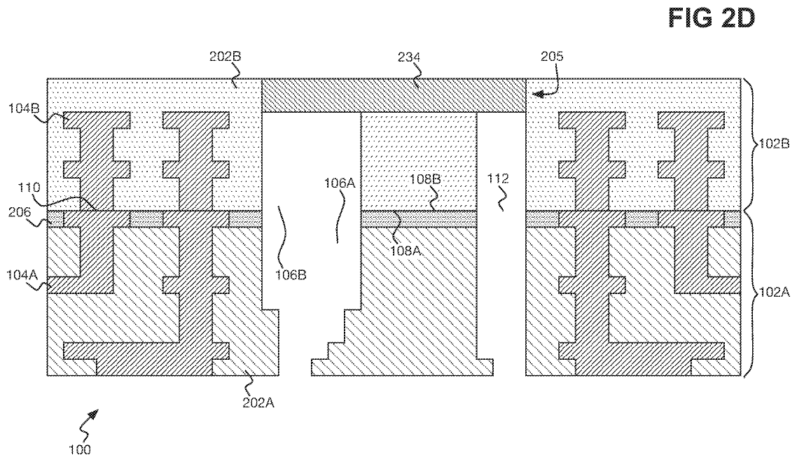

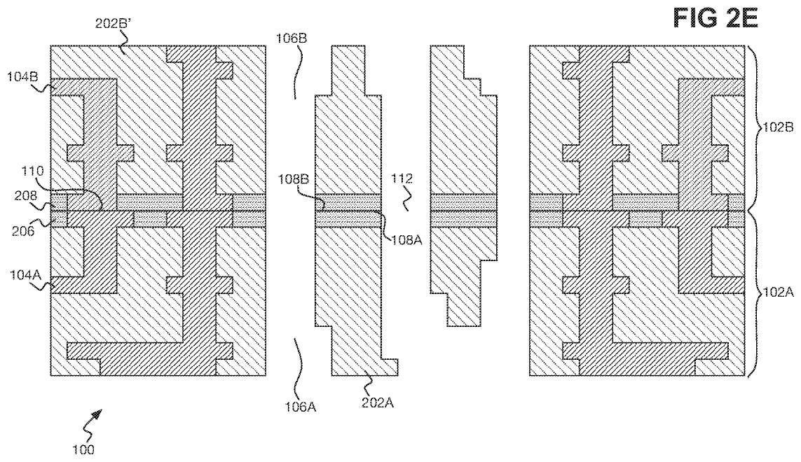

FIGS. 2A, 2B, 2C, 2D, and 2E show different examples of the device 100. In each of the examples, the substrate 102A includes at least one non-silicon layer 202A within which the electrical conductors 104A and the fluid channels 106A have been formed. The substrate 102A further includes a dielectric or amorphous silicon layer 206 having the surface 108A at which the conductors 104A and the channels 106A are exposed. In the case in which the layer 206 is a dielectric layer, the layer 206 may be a silicon nitride, silicon carbide, silicon oxide, or titanium oxide layer, for instance.

The substrate 102A includes the dielectric or amorphous silicon layer 206 so that the substrate 102A can be plasma bonded to the substrate 102B. That is, the non-silicon layer 202A may itself not form a strong plasma bond with the substrate 102B, or may not be able to be plasma bonded to the substrate 102B. The dielectric or amorphous silicon layer 206 therefore is adapted to promote plasma bonding of the substrate 102A to the substrate 102B.

In FIG. 2A, the substrate 102B includes at least one silicon substrate layer 202B within or on which a device layer 205 has been formed. The silicon substrate layer 202B can itself form a strong plasma bond with the substrate 102A, such that an (additional) dielectric or amorphous silicon layer does not have to be included. The device layer 205 includes an IC 204, such as a processor.

The electrical conductors 104B exposed at the surface 108B of the silicon substrate layer 202B are conductively interconnected with respective of the conductors 104A exposed at the surface 108A of the dielectric or amorphous silicon layer 206 via direct electrical interconnects 110. The fluidic channels 106B exposed at the surface 108B are fluidically interconnected with respective of the channels 106A exposed at the surface 108A via direct fluidic interconnects 112.

Therefore, electrical power can be provided from the substrate 102A to the substrate 102B via the direct electrical interconnects 110 to power the IC 204. Electrical data communication signals can be exchanged to and from the IC 204 in the substrate 102B and the substrate 102A via the direct electrical interconnects 110. Cooling fluid can be supplied from the fluidic channels 106A to the fluidic channels 106B via the direct fluidic interconnects 112 to recirculate past the IC 204 in order to cool the IC 204. The example of FIG. 2A shows that plasma bonding can be used to form an actively cooled microprocessor device.

In FIG. 2B, the substrate 102B again includes at least one silicon substrate layer 202B within or on which the device layer 205 has been formed. The silicon substrate layer 202B can itself form a strong plasma bond with the substrate 102A, such that an (additional) dielectric or amorphous silicon layer does not have to be included. The device layer 205 includes one or multiple photonic ICs 214 that can optically receive and transmit (i.e., communicate) data via light (i.e., photons).

The conductors 104B exposed at the surface 108B are again conductively interconnected with respective of the conductors 104A exposed at the surface 108A via direct electrical interconnects 110. The fluidic channels 106B exposed at the surface 108B are again fluidically interconnected with respective of the channels 106A exposed at the surface 108A via direct fluidic interconnects 112. Therefore, electrical power can be provided from the substrate 102A to the substrate 102B via the direct electrical interconnects 110 to power the photonic ICs 214.

Optical data communication signals can be exchanged to and from each photonic IC 214 in the substrate 102B and the substrate 102A via the direct fluidic interconnect 112 between corresponding channels 106A and 106B. That is, photons transmitted by a photonic IC 214 travel from an adjacent channel 106B to a corresponding directly interconnected channel 106A for outwards transmission from the device 100. Photons externally received by the device 100 at a channel 106A travel inwards to a corresponding directly interconnected channel 106B for receipt by the adjacent photonic IC 214. The example of FIG. 2B shows that plasma bonding can be used to form a photonic communication device.

In FIG. 2C, the substrate 102B again includes at least one silicon substrate layer 202B within or on which the device layer 205 has been formed. The silicon substrate layer 202B can itself form a strong plasma bond with the substrate 102A, such that an (additional) dielectric or amorphous silicon layer does not have to be included. The device layer 205 includes one or multiple sensing ICs 224 that can sense (e.g., measure) physical, electrical, or other characteristics of a gaseous or liquid fluidic sample, such as temperature, humidity, light, viscosity, resistance, capacitance, and so on.

The conductors 104B exposed at the surface 108B are again conductively interconnected with respective of the conductors 104A exposed at the surface 108A via direct electrical interconnects 110. The channels 106B exposed at the surface 108B are again fluidically interconnected with the channels 106A exposed at the surface 108A via direct fluidic interconnects 112.

Therefore, electrical power can be provided from the substrate 102A to the substrate 102B via the direct electrical interconnects 110 to power the sensing ICs 224. Sensing result signals can be transmitted from the ICs 224 in the substrate 102B to the substrate 102A, and control signals can be transmitted from the substrate 102A to the ICs 224, via the direct electrical interconnects 110. The fluidic sample that the ICs 224 are to sense can be provided from the fluidic channels 106A to the fluidic channels 106B via the direct fluidic interconnects 112. The example of FIG. 2C shows that plasma bonding can be used to form a fluid sensing (e.g., measuring) device.

In FIG. 2D, the substrate 102B as before may include at least one silicon substrate layer 202B within or on which the device layer 205 has been formed. The silicon substrate layer 202B can itself form a strong plasma bond with the substrate 102A, such that an (additional) dielectric or amorphous silicon layer does not have to be included. The device layer 205 may be a glass or transparent layer including a microfluidics sensor 234 made up of microfluidic channels to mix a fluidic sample with a reagent to provide visual indication of presence or absence of a material of interest within the fluidic sample, such as a virus or other molecule. Such a microfluidics sensor 234 may be a polymerase chain reaction (PCR) sensor, for instance.

The conductors 104B exposed at the surface 108B are as before conductively interconnected with respective of the conductors 104A exposed at the surface 108A via direct electrical interconnects 110. The channels 106B exposed at the surface 108B are as before fluidically interconnected with respective of the channels 106A exposed at the surface 108A via direct fluidic interconnects 112.

Therefore, electrical power can be provided from the substrate 102A to the substrate 102B via the direct electrical interconnects 110 to power any electrical components in the substrate 102B. Electrical data communication signals can be exchanged to and from any electrical components in the substrate 102B and the substrate 102A via the direct electrical interconnects 110. A fluidic sample and a reagent may be provided for mixing within the sensor 234 from respective fluidic channels 106A to respective fluidic channels 106B via the direct fluidic interconnects 112. The example of FIG. 2D shows that plasma bonding can be used to form a microfluidics sensor device.

In FIG. 2E, the substrate 102B may be similar to the substrate 102A, and includes at least one non-silicon layer 202B′ within which the electrical conductors 104B and the fluid channels 106B have been formed. The substrate 102B further includes a dielectric or amorphous silicon layer 208 having the surface 108B at which the conductors 104B and the channels 106B are exposed. As with the substrate 102A having the dielectric or amorphous silicon layer 206, the substrate 102B includes the dielectric or amorphous silicon layer 208 so that the substrate 102B can be plasma bonded to the substrate 102A.

The conductors 104B exposed at the surface 108B are as before conductively interconnected with respective of the conductors 104A exposed at the surface 108A via direct electrical interconnects 110. The channels 106B exposed at the surface 108B are as before fluidically interconnected with respective of the channels 106A exposed at the surface 108A via direct fluidic interconnects 112. The example of FIG. 2E shows that plasma bonding can be used to construct a device 100 from multiple substrates 102A and 102B of the same type.

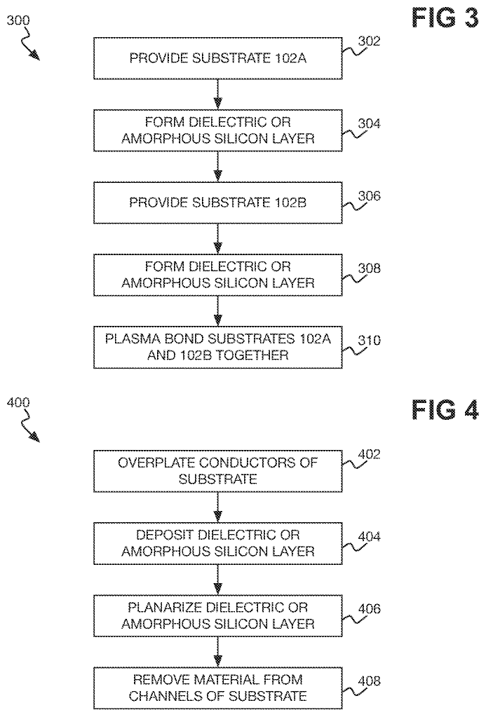

FIG. 3 shows an example method 300 for fabricating a device 100. The method 300 includes providing a first substrate 102A having one or multiple first conductors 104A and one or multiple first channels 106A (302). If the substrate 102A is not a silicon substrate, or the conductors 104A and the channels 106A are not exposed at the substrate 102A at a dielectric or amorphous silicon layer 206, then the method 300 includes forming such a dielectric or amorphous silicon layer 206 adjacent to a non-silicon layer 202A of the substrate 102A (304). Formation of the dielectric or amorphous silicon layer 206 ensures that the substrate 102A can be plasma bonded at the surface 108A.

The method 300 similarly includes providing a second substrate 102B having one or multiple first conductors 104B and one or multiple second channels 106B (306). If the substrate 102B is not a silicon substrate, or the conductors 104B and the channels 106B are not exposed at the substrate 102B at a dielectric or amorphous silicon layer 208, then the method 300 includes forming such a dielectric or amorphous silicon layer 208 adjacent to a non-silicon layer 202B′ of the substrate 102B (308). Formation of the dielectric or amorphous silicon layer 208 ensures that the substrate 102B can be plasma bonded at the surfaces 108B.

The method 300 includes then plasma bonding the substrates 102A and 102B at their respective surfaces 108A and 108B (310). Plasma bonding forms direct electrical interconnects 110 between the conductors 104A exposed at the surface 108A and the conductors 104B exposed at the surface 108B. Plasma bonding forms direct fluidic interconnects 112 between the channels 106A exposed at the surface 108A and the channels 106B exposed at the surface 108B.

The method 300 therefore covers the following general cases. First, each of the substrates 102A and 102B may not be a silicon substrate and/or may not already have a corresponding dielectric or amorphous silicon layer 206 or 208. In this case, both 304 and 308 are performed to prepare the substrates 102A and 102B so that they can be plasma bonded together. Second, each of the substrates 102A and 102B may be a silicon substrate and/or may already have a corresponding dielectric or amorphous silicon layer 206 or 208. In this case, neither 304 nor 308 is performed.

Third, the substrate 102A may not be a silicon substrate or may not already have a dielectric or amorphous silicon layer 206, and the substrate 102B may be a silicon substrate or already have a dielectric or amorphous silicon layer 208. In this case, 304 is performed and 308 is not performed. Fourth, the substrate 102A may be a silicon substrate or may already have a dielectric or amorphous silicon layer 206, and the substrate 102B may not be a silicon substrate and not already have a dielectric or amorphous silicon layer 208. In this case, 304 is not performed and 308 is performed.

FIG. 4 shows an example method 400 for forming a dielectric or amorphous silicon layer 206 or 208 on a substrate 102A or 102B that is not a silicon substrate and does not already have such a layer 206 or 208, in 304 or 308 of the method 300. The method 400 is described in relation to the substrate 102A not being a silicon substrate and not already having a dielectric or amorphous silicon layer 206. However, the method 400 is similarly performed for a substrate 102B not being a silicon substrate and not already have a dielectric or amorphous silicon layer 208.

The method 400 pertains to the case in which the substrate 102A as provided in 302 of the method 300 has its channels 106A filled with material within the non-silicon layer 202A. The material may be the same conductive material as that which forms the conductors 104A. If the substrate 102A is not provided with its channels 106A filled with material, then the channels 106A are first filled with material prior to (or as a part of) the method 400 being performed.

The method 400 includes overplating the conductors 104A of the substrate 102A as exposed at the non-silicon layer 202A (402). The method 400 includes depositing a dielectric or amorphous silicon layer 206 over the non-silicon layer 202A, covering the conductors 104A and the channels 106A as filled with material (404). Such deposition may include performing a sol-gel process, an atomic layer deposition process, an electron-beam deposition process, a plasma-enhanced chemical vapor deposition process, or a sputtering process, for instance.

The method 400 includes then planarizing the dielectric or amorphous silicon layer 206, such as via chemical-mechanical polishing (CMP), to expose at the layer 206 the conductors 104A but not the channels 106A as filled with material (406). The material within the channels 106A protects the channels from debris during deposition in 404 and planarization in 406, ensuring that the channels 106A remain accurately defined during deposition and planarization of the dielectric or amorphous silicon layer 206. The method 400 includes removing the material from the channels 106A of the substrate 102A (408), such as via selectively etching the material using photolithographic techniques in the case in which the material is the same conductive material as the conductors 104A.

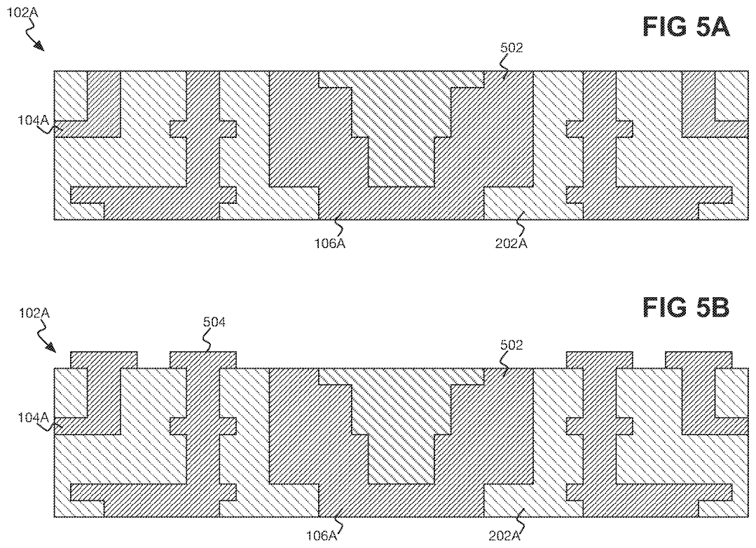

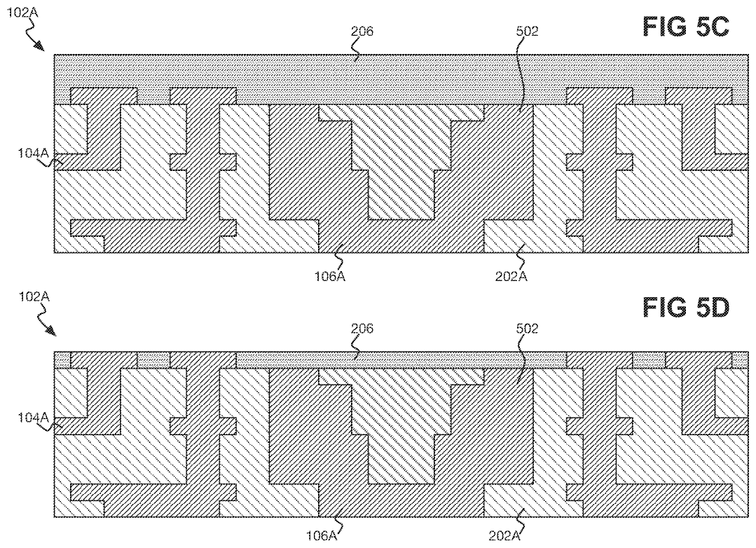

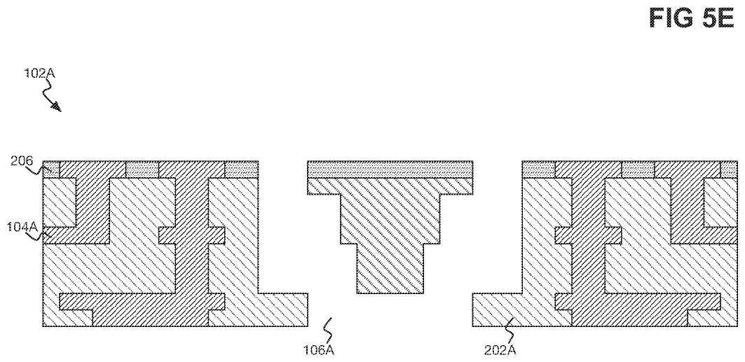

FIGS. 5A, 5B, 5C, and 5D show example performance of the method 400 in relation to the case in which a substrate 102A is provided in 302 of the method 300 that is not a silicon substrate and does not already have a dielectric or amorphous silicon layer 206. In FIG. 5A, a substrate 102A is specifically provided in 302 of the method 300 that has at least one non-silicon layer 202A at which conductors 104A and channels 106A filled with material 502 are exposed. The material 502 may be the same material as that of the conductors 104A.

In FIG. 5B, the conductors 104A of the substrate 102A are plated with conductive material 504 where the conductors 104A are exposed at the non-silicon layer 202A. The conductive material 504 may be the same material as that of the conductors 104A (and/or the same material 502 filling the channels 106A), and the overplated conductive material 504 becomes part of the conductors 104A. In FIG. 5C, a dielectric or amorphous silicon layer 206 is deposited over the non-silicon layer 202A of the substrate 102A, covering both the overplated conductors 104A as well as the channels 106A filled with the material 502.

In FIG. 5D, the dielectric or amorphous silicon layer 206 of the substrate 102A is planarized to expose the overplated conductors 104A at the layer 206. However, the channels 106A remain filled with the material 502 and covered by the dielectric or amorphous silicon layer 206. Therefore, in FIG. 5E, the material 502 is removed from the channels 106A, as is the dielectric or amorphous silicon layer 206 where the layer 206 covers the channels 106A, to expose and open the channels 106A at the dielectric or amorphous silicon layer 206 through, for example, photolithography and/or a wet etch process.

Plasma bonding formation of both direct electrical interconnects and direct fluidic interconnects has been described. Two or more substrates can be stacked together via such plasma bonding. If a substrate is not a silicon substrate or does not already have a dielectric or amorphous silicon layer, such a layer can be formed to promote subsequent plasma bonding of the substrate with another substrate.

1. A device comprising:
a first substrate having one or multiple first channels and one or multiple first conductors that are exposed at a first surface of the first substrate; and
a second substrate having one or multiple second channels and one or multiple second conductors that are exposed at a second surface of the first substrate,
wherein the first and second substrates are plasma bonded together at the first and second surfaces, forming direct electrical interconnects between the first and second conductors and direct fluidic interconnects between the first and second channels.

2. (canceled)

3. The device of claim 1, wherein the first substrate comprises:
a non-silicon layer having a surface at which the first channels and the first conductors are exposed; and
a dielectric or amorphous silicon layer adjacent to the non-silicon layer, at which the first channels and the first conductors are exposed, and having a surface corresponding to the first surface,
wherein the dielectric or amorphous silicon layer is adapted to promote plasma bonding of the first and second substrates together.

4-8. (canceled)

9. The device of claim 3, wherein the second substrate comprises:
a silicon substrate layer having a surface corresponding to the second surface and at which the second channels and the second conductors are exposed; and
a device layer within or on the silicon substrate layer.

10. The device of claim 9, wherein the device layer comprises an integrated circuit (IC),
and wherein the first channels are to supply fluid via the direct fluidic interconnects to the second channels to cool the IC.

11. The device of claim 9, wherein the device layer comprises a photonic integrated circuit (IC),
and wherein the first channels are to communicate photons via the direct fluidic interconnects to and from the photonic IC to communicate data to and from the photonic IC.

12. The device of claim 9, wherein the device layer comprises a sensing integrated circuit (IC) to sense a fluidic sample,
wherein the first channels are to provide the fluidic sample via the direct fluidic interconnects to the second channels to provide to the sensing IC.

13. The device of claim 9, wherein the device layer comprises a microfluidics sensor to provide visual indication of presence or absence of a material of interest within a fluidic sample,
wherein the first channels are to provide the fluidic sample via the direct fluidic interconnects to the second channels to provide to the microfluidics sensor.

14. The device of claim 3, wherein the second substrate comprises:
one or multiple layers of a molding compound, including a non-silicon layer at which the second channels and the second conductors are exposed; and
a dielectric or amorphous silicon layer adjacent to the non-silicon layer and at which the second channels and the second conductors are exposed,
wherein a surface of the dielectric or amorphous silicon layer corresponds to the second surface.

15. A substrate comprising:
a non-silicon layer having a surface at which one or multiple first channels and one or multiple first conductors are exposed; and
a dielectric or amorphous silicon layer adjacent to the non-silicon layer and at which the first channels and the first conductors are exposed,
wherein the dielectric or amorphous silicon layer is adapted to promote plasma bonding of the substrate with another substrate having one or multiple second channels and one or multiple second conductors to form direct electrical interconnects between the first and second conductors and direct fluidic interconnects between the first and second channels.

16-17. (canceled)

18. The substrate of claim 15, further comprising:
one or multiple layers of a molding compound, including the non-silicon layer.

19. The substrate of claim 18, wherein the molding compound comprises epoxy molding compound.

20. The substrate of claim 18, wherein the substrate comprises a molded interconnect substrate (MIS).

21. A method comprising:
providing a first substrate having one or multiple first channels and one or multiple first conductors;
providing a second substrate having one or multiple second channels and one or multiple second conductors; and
plasma bonding the first and second substrates together,
wherein plasma bonding the first and second substrates together forms direct electrical interconnects between the first and second conductors and direct fluidic interconnects between the first and second channels.

22. The method of claim 21, wherein the first substrate comprises a non-silicon layer at which the first conductors and the first channels are exposed, the first channels are filled with material within the non-silicon layer, and the method further comprises:
forming a dielectric or amorphous silicon layer adjacent to the non-silicon layer, at which the first channels and the first conductors are exposed, and that is adapted to promote plasma bonding of the first and second substrates together.

23. The method of claim 22, wherein the dielectric or amorphous silicon layer comprises a silicon oxide layer, a silicon nitride layer, a silicon carbide layer, or a titanium oxide layer.

24-26. (canceled)

27. The method of claim 22, wherein forming the dielectric or amorphous silicon layer comprises:
overplating the first conductors as exposed at the non-silicon layer;
depositing a dielectric or amorphous silicon layer over the non-silicon layer, covering the first conductors and the first channels as filled with the material;
planarizing the dielectric or amorphous silicon layer, exposing the first conductors at the dielectric or amorphous silicon layer; and
removing the material from the first channels.

28. The method of claim 27, wherein the material in the first channels protects the first channels from debris during deposition and/or planarization of the dielectric or amorphous silicon layer.

29. The method of claim 27, wherein depositing the dielectric or amorphous layer over the non-silicon layer comprises performing a sol-gel process, an atomic layer deposition process, an electron-beam deposition process, a plasma-enhanced chemical vapor deposition process, or a sputtering process.

30. The method of claim 27, wherein planarizing the dielectric or amorphous silicon layer comprises performing chemical-mechanical polishing.

31. The method of claim 27, wherein the material is a conductive material of the first conductors, and removing the material from the first channels comprising:
selectively etching the conductive material to remove the conductive material from the first channels but not the first conductors.

32-41. (canceled)
